(19) United States
(12) Patent Application Publication
(10) Pub. No.: US 2024/0427967 A1
(43) Pub. Date: Dec. 26, 2024

(54) Monotonic Machine Learning-Based Sub-Resolution Assist Features

(71) Applicant: Siemens Industry Software Inc., Plano, TX (US)

(72) Inventors: Yuansheng Ma, Fremont, CA (US); Le Hong, Benicia, CA (US); Junjiang Lei, Reno, NV (US)

(73) Assignee: Siemens Industry Software Inc., Plano, TX (US)

(21) Appl. No.: 18/337,907

(22) Filed: Jun. 20, 2023

(51) Int. Cl. G06F 30/27; G06F 30/392

(52) U.S. Cl. CPC G06F 30/27; G06F 30/392

(57) ABSTRACT

Layout features in a layout design are classified into groups of layout features. A machine learning-based SRAF generation process is then performed to generate sub-resolution assist features for layout features in each of the groups of layout features. Each of the groups of layout features has a specific machine learning model. The machine learning-based SRAF generation process comprising: dividing regions where sub-resolution assist features are likely to be placed into areas of interest, extracting a feature vector for each of the areas of interest based on a layout area centered at the each of the areas of interest, determining whether the each of the areas of interest should be part of a sub-resolution assist feature by using the feature vector as an input of the specific machine learning model, and generating the sub-resolution assist features based on results of the determining.

### FIELD OF THE DISCLOSED TECHNOLOGY

The present disclosed technology relates to the field of circuit design and manufacture. Various implementations of the disclosed technology may be particularly useful for optical proximity correction.

### BACKGROUND OF THE DISCLOSED TECHNOLOGY

As designers and manufacturers continue to shrink the size of circuit components, the shapes reproduced on the substrate (wafer) though photolithography become smaller and are placed closer together. This reduction in feature size and spacing increases the difficulty of faithfully reproducing the image onto the substrate intended by the design layout and can create flaws in the manufactured device. To address the problem, one or more resolution enhancement techniques are often employed to improve the resolution of the image that the mask forms on the substrate during the photolithographic process.

One of resolution enhancement techniques, “optical proximity correction” or “optical process correction” (OPC), tries to compensate for light diffraction effects. When light illuminates the photomask, the transmitted light diffracts. The higher spatial frequencies the regions of the mask have, the higher angles the light diffracts at. The resolution limits of the lens in a photolithographic system make the lens act effectively as a low-pass filter for the various spatial frequencies in the two-dimensional layout. This can lead to optical proximity effects such as a pull-back of line-ends from their desired position, corner rounding and a bias between isolated and dense structures (the so-called iso-dense bias problem). The optical proximity correction adjusts the amplitude of the light transmitted through a lithographic mask by modifying the layout design data employed to create the photomask. For example, edges in the layout design may be adjusted to make certain portions of the geometric elements larger or smaller, in accordance with how much additional light exposure (or lack of exposure) is desired at certain points on the substrate. When these adjustments are appropriately calibrated, overall pattern fidelity is greatly improved, thereby reducing optical proximity effects.

OPC can be rule-based, model-based, or both. In rule-based OPC, the proximity effects are characterized and specific solutions are devised for specific geometric configurations. The layout design is then searched using a DRC tool or a geometric-based software engine to find these geometric configurations. Once they are found, the specific solutions are applied. Rule-based OPC approaches work well for simple cases. For complex layout features, however, model-based OPC approaches need to be employed to obtain desired results. Model-based OPC performs simulation to predict the printed image, which guides layout modifications.

Another way to implement the OPC technique involves adding geometric elements (sub-resolution assist features, or SRAFs) in the layout design. While the conventional OPC approach certainly corrects many proximity effects, it does not address one proximity effect—variations in focus condition, which can cause the previously mentioned iso-dense bias problem. The variations in focus condition become significant when an off-axis illumination scheme is optimized for greatest depth of focus of densely placed features. SRAFs, which are themselves intended to not print, can reduce the impact of the iso-dense bias problem by making a relatively isolated main feature behave lithographically more like a densely-placed main feature. For example, scattering bars, a common type of SRAFs, may be placed adjacent to relatively isolated lines (main features), allowing the isolated lines to diffract light like dense lines. Here, a main feature is referred to as a feature that is intended to print. Off-axis illumination is one of the three major resolution enhancement technologies (the other two being phase shift masks and optical proximity correction) and has been widely employed. Accordingly, SRAF implementation has become a crucial technique in advanced semiconductor manufacturing.

Recently inverse lithography technology (ILT) has become mainstream for the advanced technology nodes. Inverse lithography technology, as the name suggested, is a mathematically inverse approach for determining mask patterns: given a known forward transformation from mask patterns to images for a specified lithography process, it computes an optimized mask that produces the desired wafer target with best pattern fidelity and/or largest process window. The optimized mask patterns are not limited to simple modifications of the target patterns. First, the optimized mask patterns derived for targeted layout features in an inverse lithography technology process tend to be curvilinear in nature, which can provide better lithographic quality than Manhattan patterns. Second, sub-resolution assist features are automatically generated in an inverse lithography technology process, unlike a conventional OPC process in which SRAFs are heuristically inserted. With curvilinear main features and sub-resolution assist features both being automatically generated, inverse lithography technology can deliver better quality of results for mask synthesis designs than conventional OPC techniques. Despite recent advances in the area of inverse lithography technology, however, the runtime problem associated with ILT computation remains a challenge for full-chip applications.

### BRIEF SUMMARY OF THE DISCLOSED TECHNOLOGY

Various aspects of the present disclosed technology relate to techniques for machine learning-based SRAF generation. In one aspect, there is a method comprising: receiving a layout design; classifying layout features in the layout design into groups of layout features; performing a machine learning-based SRAF generation process to generate sub-resolution assist features for layout features in each of the groups of layout features, each of the groups of layout features having a specific machine learning model for determining whether a small area should be part of a sub-resolution assist feature, size and shape of the small area being preset, the machine learning-based SRAF generation process comprising: dividing regions where sub-resolution assist features are likely to be placed into areas of interest, each of the areas of interest having the same size and shape as the small area, extracting a feature vector for each of the areas of interest based on a layout area centered at the each of the areas of interest, determining whether the each of the areas of interest should be part of a sub-resolution assist feature by using the feature vector as an input of the specific machine learning model, and generating the sub-resolution assist features based on results of the determining; and storing information of the sub-resolution assist features.

The method may further comprise: combining the sub-resolution assist features with modified layout features to generate a first processed layout design, the modified layout features being generated by performing a first optical proximity correction process on the layout features in the layout design; and performing a second optical proximity correction process on the first processed layout design to generate a second processed layout design which is to be used to manufacture photo masks. The first optical proximity correction process may be a machine learning-based main feature generation process which generates the modified layout features for layouts features in each of the groups of layout features using a particular machine learning model for the each of the groups of layout features.

The method may still further comprise: manufacturing photo masks based on the second processed layout design.

The specific machine learning model may be trained using training samples labeled based on sub-resolution assist features generated by an inverse lithography technology (ILT) tool. The small area used by specific machine learning model may be a square with a side length smaller than 50 nm. The layout area centered at each of the areas of interest may have a dimension smaller than 1 micron.

The generating the sub-resolution assist features based on results of the determining may comprise: combining areas of interest determined to be part of a sub-resolution assist feature to form intermediate sub-resolution assist features; and processing the intermediate sub-resolution assist features to derive the sub-resolution assist features.

The classifying layout features may be a machine learning-based clustering process. The machine learning-based clustering process may comprise: extracting a feature vector for each of the layout features; and mapping the set of feature vectors into hyperboxes of a hyperspace.

In another aspect, there is one or more computer-readable media storing computer-executable instructions for causing one or more processors to perform the above method.

In still another aspect, there is a system, comprising: one or more processors, the one or more processors programmed to perform the above method.

Certain inventive aspects are set out in the accompanying independent and dependent claims. Features from the dependent claims may be combined with features of the independent claims and with features of other dependent claims as appropriate and not merely as explicitly set out in the claims.

Certain objects and advantages of various inventive aspects have been described herein above. Of course, it is to be understood that not necessarily all such objects or advantages may be achieved in accordance with any particular embodiment of the disclosed technology. Thus, for example, those skilled in the art will recognize that the disclosed technology may be embodied or carried out in a manner that achieves or optimizes one advantage or group of advantages as taught herein without necessarily achieving other objects or advantages as may be taught or suggested herein.

### BRIEF DESCRIPTION OF THE DRAWINGS

FIG. 1 illustrates an example of a computing system that may be used to implement various embodiments of the disclosed technology.

FIG. 2 illustrates an example of a multi-core processor unit that may be used to implement various embodiments of the disclosed technology.

FIG. 3A illustrates an example of a mask pattern after one iteration.

FIG. 3B illustrates an example of a mask pattern after 20 iterations.

FIG. 4 illustrates an example of a SRAF generation tool that may be implemented according to various embodiments of the disclosed technology.

FIG. 5 illustrates a flowchart showing a monotonic machine learning-based SRAF generation process that may be implemented according to various examples of the disclosed technology.

FIG. 6 illustrates a flowchart showing a process for using a hyperspace-based machine learning technique to classify layout features that may be implemented according to various examples of the disclosed technology.

FIG. 7 illustrates an example clustering result from a hyperspace-based machine learning process.

FIG. 8 illustrates another example clustering result from a hyperspace-based machine learning process.

FIG. 9 illustrates a flowchart showing a process for generating sub-resolution assist features for each of the groups of layout features that may be implemented according to various examples of the disclosed technology.

FIG. 10A illustrates an example of regions where sub-resolution assist features are likely to be placed being dividing into areas of interest.

FIG. 10B illustrates another example of regions where sub-resolution assist features are likely to be placed being dividing into areas of interest.

### DETAILED DESCRIPTION OF THE DISCLOSED TECHNOLOGY

### General Considerations

Various aspects of the present disclosed technology relate to techniques for machine learning-based SRAF generation. In the following description, numerous details are set forth for the purpose of explanation. However, one of ordinary skill in the art will realize that the disclosed technology may be practiced without the use of these specific details. In other instances, well-known features have not been described in detail to avoid obscuring the present disclosed technology.

Some of the techniques described herein can be implemented in software instructions stored on a computer-readable medium, software instructions executed on a computer, or some combination of both. Some of the disclosed techniques, for example, can be implemented as part of an electronic design automation (EDA) tool. Such methods can be executed on a single computer or on networked computers.

Although the operations of the disclosed methods are described in a particular sequential order for convenient presentation, it should be understood that this manner of description encompasses rearrangements, unless a particular ordering is required by specific language set forth below. For example, operations described sequentially may in some cases be rearranged or performed concurrently. Moreover, for the sake of simplicity, the disclosed flow charts and block diagrams typically do not show the various ways in which particular methods can be used in conjunction with other methods. Additionally, the detailed description sometimes uses terms like “perform”, “determine”, “classify”, and “generate” to describe the disclosed methods. Such terms are high-level abstractions of the actual operations that are performed. The actual operations that correspond to these terms will vary depending on the particular implementation and are readily discernible by one of ordinary skill in the art.

Also, as used herein, the term “design” is intended to encompass data describing an entire integrated circuit device. This term also is intended to encompass a smaller group of data describing one or more components of an entire device, however, such as a portion of an integrated circuit device. Still further, the term “design” also is intended to encompass data describing more than one micro device, such as data to be used to form multiple micro devices on a single wafer.

### Illustrative Operating Environment

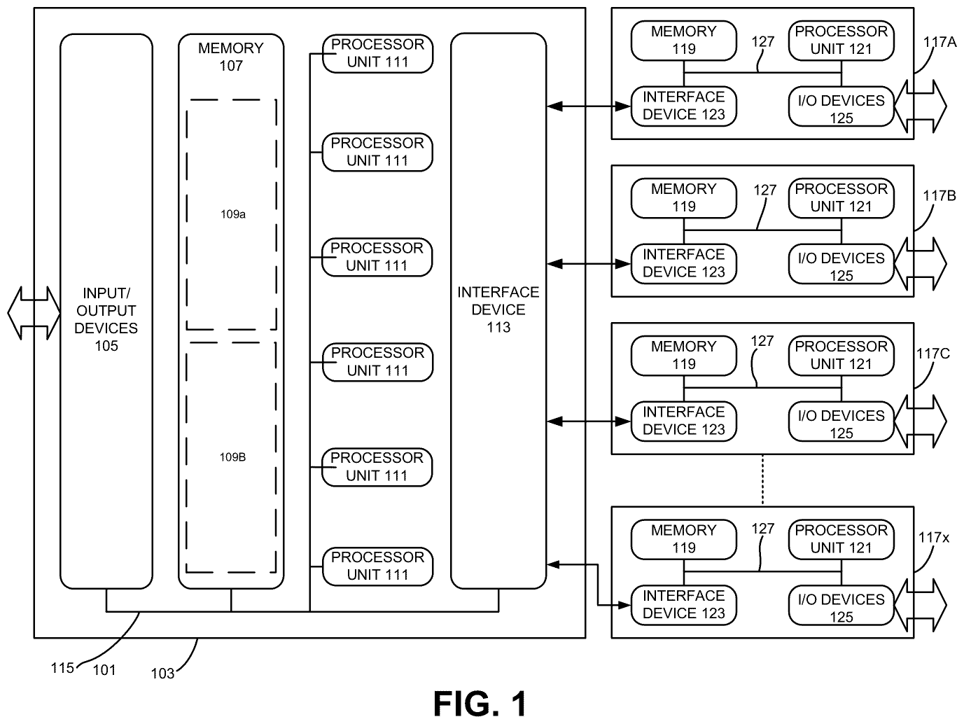

The execution of various electronic design automation processes according to embodiments of the disclosed technology may be implemented using computer-executable software instructions executed by one or more programmable computing devices. Because these embodiments of the disclosed technology may be implemented using software instructions, the components and operation of a generic programmable computer system on which various embodiments of the disclosed technology may be employed will first be described. Further, because of the complexity of some electronic design automation processes and the large size of many circuit designs, various electronic design automation tools are configured to operate on a computing system capable of simultaneously running multiple processing threads. The components and operation of a computer network having a host or master computer and one or more remote or servant computers therefore will be described with reference to FIG. 1. This operating environment is only one example of a suitable operating environment, however, and is not intended to suggest any limitation as to the scope of use or functionality of the disclosed technology.

In FIG. 1, the computer network 101 includes a master computer 103. In the illustrated example, the master computer 103 is a multi-processor computer that includes a plurality of input and output devices 105 and a memory 107. The input and output devices 105 may include any device for receiving input data from or providing output data to a user. The input devices may include, for example, a keyboard, microphone, scanner or pointing device for receiving input from a user. The output devices may then include a display monitor, speaker, printer or tactile feedback device. These devices and their connections are well known in the art, and thus will not be discussed at length here.

The memory 107 may similarly be implemented using any combination of computer readable media that can be accessed by the master computer 103. The computer readable media may include, for example, microcircuit memory devices such as read-write memory (RAM), read-only memory (ROM), electronically erasable and programmable read-only memory (EEPROM) or flash memory microcircuit devices, CD-ROM disks, digital video disks (DVD), or other optical storage devices. The computer readable media may also include magnetic cassettes, magnetic tapes, magnetic disks or other magnetic storage devices, punched media, holographic storage devices, or any other medium that can be used to store desired information.

As will be discussed in detail below, the master computer 103 runs a software application for performing one or more operations according to various examples of the disclosed technology. Accordingly, the memory 107 stores software instructions 109A that, when executed, will implement a software application for performing one or more operations. The memory 107 also stores data 109B to be used with the software application. In the illustrated embodiment, the data 109B contains process data that the software application uses to perform the operations, at least some of which may be parallel.

The master computer 103 also includes a plurality of processor units 111 and an interface device 113. The processor units 111 may be any type of processor device that can be programmed to execute the software instructions 109A, but will conventionally be a microprocessor device. For example, one or more of the processor units 111 may be a commercially generic programmable microprocessor, such as Intel® Pentium® or Xeon™ microprocessors, Advanced Micro Devices Athlon™ microprocessors or Motorola 68K/Coldfire® microprocessors. Alternately or additionally, one or more of the processor units 111 may be a custom-manufactured processor, such as a microprocessor designed to optimally perform specific types of mathematical operations. The interface device 113, the processor units 111, the memory 107 and the input/output devices 105 are connected together by a bus 115.

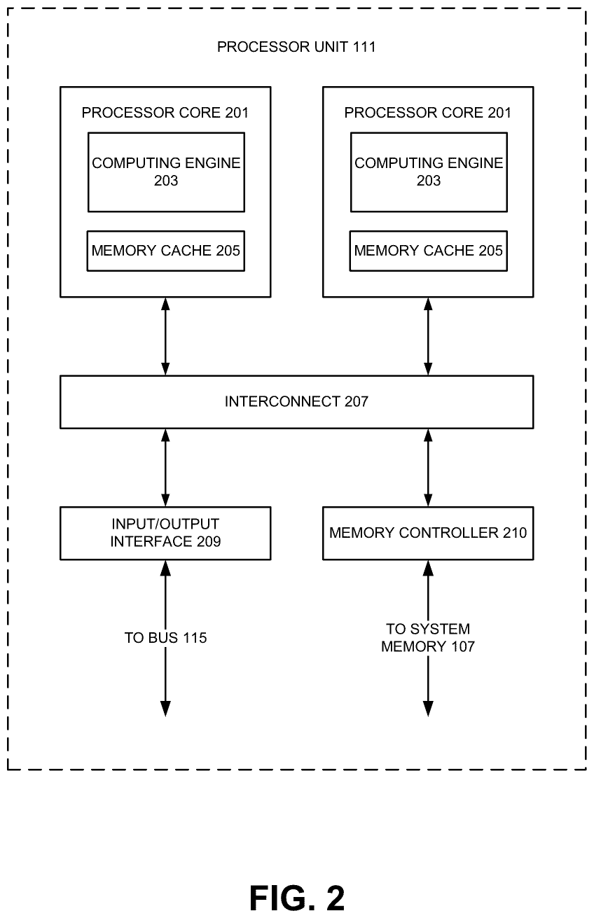

With some implementations of the disclosed technology, the master computing device 103 may employ one or more processing units 111 having more than one processor core. Accordingly, FIG. 2 illustrates an example of a multi-core processor unit 111 that may be employed with various embodiments of the disclosed technology. As seen in this figure, the processor unit 111 includes a plurality of processor cores 201. Each processor core 201 includes a computing engine 203 and a memory cache 205. As known to those of ordinary skill in the art, a computing engine contains logic devices for performing various computing functions, such as fetching software instructions and then performing the actions specified in the fetched instructions. These actions may include, for example, adding, subtracting, multiplying, and comparing numbers, performing logical operations such as AND, OR, NOT and XOR, and retrieving data. Each computing engine 203 may then use its corresponding memory cache 205 to quickly store and retrieve data and/or instructions for execution.

Each processor core 201 is connected to an interconnect 207. The particular construction of the interconnect 207 may vary depending upon the architecture of the processor unit 111. With some processor cores 201, such as the Cell microprocessor created by Sony Corporation, Toshiba Corporation and IBM Corporation, the interconnect 207 may be implemented as an interconnect bus. With other processor units 111, however, such as the Opteron™ and Athlon™ dual-core processors available from Advanced Micro Devices of Sunnyvale, California, the interconnect 207 may be implemented as a system request interface device. In any case, the processor cores 201 communicate through the interconnect 207 with an input/output interface 209 and a memory controller 210. The input/output interface 209 provides a communication interface between the processor unit 111 and the bus 115. Similarly, the memory controller 210 controls the exchange of information between the processor unit 111 and the system memory 107. With some implementations of the disclosed technology, the processor units 111 may include additional components, such as a high-level cache memory accessible shared by the processor cores 201.

While FIG. 2 shows one illustration of a processor unit 111 that may be employed by some embodiments of the disclosed technology, it should be appreciated that this illustration is representative only, and is not intended to be limiting. Also, with some implementations, a multi-core processor unit 111 can be used in lieu of multiple, separate processor units 111. For example, rather than employing six separate processor units 111, an alternate implementation of the disclosed technology may employ a single processor unit 111 having six cores, two multi-core processor units each having three cores, a multi-core processor unit 111 with four cores together with two separate single-core processor units 111, etc.

Returning now to FIG. 1, the interface device 113 allows the master computer 103 to communicate with the servant computers 117A, 117B, 117C . . . 117x through a communication interface. The communication interface may be any suitable type of interface including, for example, a conventional wired network connection or an optically transmissive wired network connection. The communication interface may also be a wireless connection, such as a wireless optical connection, a radio frequency connection, an infrared connection, or even an acoustic connection. The interface device 113 translates data and control signals from the master computer 103 and each of the servant computers 117 into network messages according to one or more communication protocols, such as the transmission control protocol (TCP), the user datagram protocol (UDP), and the Internet protocol (IP). These and other conventional communication protocols are well known in the art, and thus will not be discussed here in more detail.

Each servant computer 117 may include a memory 119, a processor unit 121, an interface device 123, and, optionally, one more input/output devices 125 connected together by a system bus 127. As with the master computer 103, the optional input/output devices 125 for the servant computers 117 may include any conventional input or output devices, such as keyboards, pointing devices, microphones, display monitors, speakers, and printers. Similarly, the processor units 121 may be any type of conventional or custom-manufactured programmable processor device. For example, one or more of the processor units 121 may be commercially generic programmable microprocessors, such as Intel® Pentium® or Xeon™ microprocessors, Advanced Micro Devices Athlon™ microprocessors or Motorola 68K/Coldfire® microprocessors. Alternately, one or more of the processor units 121 may be custom-manufactured processors, such as microprocessors designed to optimally perform specific types of mathematical operations. Still further, one or more of the processor units 121 may have more than one core, as described with reference to FIG. 2 above. For example, with some implementations of the disclosed technology, one or more of the processor units 121 may be a Cell processor. The memory 119 then may be implemented using any combination of the computer readable media discussed above. Like the interface device 113, the interface devices 123 allow the servant computers 117 to communicate with the master computer 103 over the communication interface.

In the illustrated example, the master computer 103 is a multi-processor unit computer with multiple processor units 111, while each servant computer 117 has a single processor unit 121. It should be noted, however, that alternate implementations of the disclosed technology may employ a master computer having single processor unit 111. Further, one or more of the servant computers 117 may have multiple processor units 121, depending upon their intended use, as previously discussed. Also, while only a single interface device 113 or 123 is illustrated for both the master computer 103 and the servant computers, it should be noted that, with alternate embodiments of the disclosed technology, either the computer 103, one or more of the servant computers 117, or some combination of both may use two or more different interface devices 113 or 123 for communicating over multiple communication interfaces.

With various examples of the disclosed technology, the master computer 103 may be connected to one or more external data storage devices. These external data storage devices may be implemented using any combination of computer readable media that can be accessed by the master computer 103. The computer readable media may include, for example, microcircuit memory devices such as read-write memory (RAM), read-only memory (ROM), electronically erasable and programmable read-only memory (EEPROM) or flash memory microcircuit devices, CD-ROM disks, digital video disks (DVD), or other optical storage devices. The computer readable media may also include magnetic cassettes, magnetic tapes, magnetic disks or other magnetic storage devices, punched media, holographic storage devices, or any other medium that can be used to store desired information. According to some implementations of the disclosed technology, one or more of the servant computers 117 may alternately or additionally be connected to one or more external data storage devices. Typically, these external data storage devices will include data storage devices that also are connected to the master computer 103, but they also may be different from any data storage devices accessible by the master computer 103.

It also should be appreciated that the description of the computer network illustrated in FIG. 1 and FIG. 2 is provided as an example only, and it not intended to suggest any limitation as to the scope of use or functionality of alternate embodiments of the disclosed technology.

### Circuit Design Flow And Optical Proximity Correction

Electronic circuits such as integrated microcircuits are used in a variety of products, enabling advances in communications, computing, healthcare, military systems, transportation, and many other applications. Designing and fabricating integrated circuit devices typically involves a series of steps, sometimes referred to as a “design flow.” The particular steps of a design flow often are dependent upon the type of integrated circuit, its complexity, the design team, and the integrated circuit fabricator or foundry that will manufacture the microcircuit. Typically, software and hardware “tools” verify the design at various stages of the design flow by running software simulators and/or hardware emulators. These steps aid in the discovery of errors in the design, and allow the designers and engineers to correct or otherwise improve the design.

Several steps are common to most design flows. Initially, the specification for a new circuit is transformed into a logical design, sometimes referred to as a register transfer level (RTL) description of the circuit. With this logical design, the circuit is described in terms of both the exchange of signals between hardware registers and the logical operations that are performed on those signals. The logical design typically employs a Hardware Design Language (HDL), such as the Very high speed integrated circuit Hardware Design Language (VHDL). The logic of the circuit is then analyzed, to confirm that it will accurately perform the functions desired for the circuit. This analysis is sometimes referred to as “functional verification.”

After the accuracy of the logical design is confirmed, it is converted into a device design by synthesis software. The device design, which is typically in the form of a schematic or netlist, describes the specific electronic devices (such as transistors, resistors, and capacitors) that will be used in the circuit, along with their interconnections. This device design generally corresponds to the level of representation displayed in conventional circuit diagrams. The relationships between the electronic devices are then analyzed to confirm that the circuit described by the device design will correctly perform the desired functions. This analysis is sometimes referred to as “formal verification.” Additionally, preliminary timing estimates for portions of the circuit are often made at this stage, using an assumed characteristic speed for each device, and incorporated into the verification process.

Once the components and their interconnections are established, the design is again transformed, this time into a physical design that describes specific geometric elements. This type of design often is referred to as a “layout” design. The geometric elements, which typically are polygons, define the shapes that will be created in various layers of material to manufacture the circuit. Automated place and route tools will be used to define the physical layouts, especially of wires that will be used to interconnect the circuit devices. Each layer of the microcircuit will have a corresponding layer representation in the layout design, and the geometric shapes described in a layer representation will define the relative locations of the circuit elements that will make up the circuit device. For example, shapes in the layer representation of a metal layer will define the locations of the metal wires used to connect the circuit devices.

Integrated circuit layout descriptions can be provided in many different formats. The Graphic Data System II (GDSII) format is a popular format for transferring and archiving two-dimensional graphical IC layout data. Among other features, it contains a hierarchy of structures, each structure containing layout elements (e.g., polygons, paths or poly-lines, circles and textboxes). Other formats include an open source format named Open Access, Milkyway by Synopsys, Inc., EDDM by Siemens Industry Software Inc., and the more recent Open Artwork System Interchange Standard (OASIS) proposed by Semiconductor Equipment and Materials International (SEMI). These various industry formats are used to define the geometrical information in IC layout designs that are employed to manufacture integrated circuits.

Before a layout design can be used by fabrication tools to manufacture the device using a photolithographic process, a designer will perform a number of verification processes. For example, the layout design may be analyzed to confirm that it accurately represents the circuit devices and their relationships described in the device design. In this process, a LVS (layout versus schematic) tool will extract a netlist from the layout design and compare it with the netlist taken from the circuit schematic. LVS can be augmented by formal equivalence checking, which checks whether two circuits perform exactly the same function without demanding isomorphism.

Process variations and technical limitations of the lithography techniques can make it difficult or even impossible to print some layout features. To achieve a high overall yield and reliability for the design, the layout design will also be analyzed to confirm that it complies with various design requirements, such as minimum spacings between geometric elements and minimum linewidths of geometric elements. A DRC (design rule checking) tool typically performs this verification process based on a set of rules specific to the semiconductor process chosen for fabrication. The set of rules is often referred to as a rule deck or just a deck. An example format of a rule deck is the Standard Verification Rule Format (SVRF) by Siemens Industry Software Inc.

Still further, the layout design may be modified to counteract limitations in the manufacturing process, etc. As mentioned previously, one or more resolution enhancement techniques (RETs) are often employed to improve the resolution of the image that the mask forms on the substrate during the photolithographic process. One of these techniques is optical proximity correction (OPC). For complex layout features, model-based OPC approaches need to be employed to obtain desired results. In a typical model-based OPC process, edges of polygons in the layout design are divided into edge fragments to allow the desired fine motion of edge fragments. Model-based OPC then performs simulation to predict the printed image. The distances between the target image and the simulated image are referred to as edge placement error (EPE). Based on edge placement errors, the edge fragments are individually moved or adjusted. The image that would be produced by a mask using the displaced edge fragments is simulated, and the new simulated image is compared with the target image, and the edge placement error for each edge fragment is again computed. This process of moving the edge fragments, simulating the image that would be produced using the moved edge fragments, and comparing the simulated image to the target image may be repeated for a number of times to ensure the simulated image for the resulting mask to reproduce the target image as much as possible. Each cycle of moving edge fragments and comparing the new simulated image to target image is referred to as an iteration of the OPC process.

Sub-resolution assistant feature (SRAF) is applied to enhance the process window of isolated and semi-isolated features by taking advantage of the optical interference between the main features and the assistant features. An SRAF, as the name implies, is a sub-resolution feature that is not meant to print. It must be carefully adjusted in size and position so that it never prints over the needed process window. This determines the most important trade-off in SRAF generation and placement: making the assist features as large and dense as possible in order to create a more dense-like mask pattern, but not so large or dense that they print. Just like the conventional OPC approach, there are rule-based SRAF and model-based SRAF methods. The rule-based SRAF methods are quite common, but have difficulty with 2D placement. For example, there is a problem of what to do with contact or via features. The model-based SRAF methods show promise for complex 2D geometries, but are difficult to implement. The rule-based SRAF methods and the model-based SRAF methods can also be combined to take advantage of both the simplicity of the former and the high quality of the latter.

### Inverse Lithography Technology

Inverse lithography technology computes an optimized mask that produces the desired wafer target with best pattern fidelity and/or largest process window in a specific lithographic process. The specific lithographic process can be represented by a transformation function which transforms mask patterns into desired wafer patterns. The transformation function can account for not only optics of the particular photolithography equipment and electromagnetics of the three-dimensional ζ3D) mask pattern, but also behavior of the photoresist in the light exposure, resist development and etching processes. Inverse lithography technology can be considered as searching for an inverse function of the transformation function. However, the transformation function may correspond to more than one inverse functions. Further, an exact mathematical solution for mask may not exist for a given inverse function. As such, inverse lithography technology typically treats the optical proximity correction problem as a constraint optimization problem over the domain of pixilated masks to be solved iteratively.

In solving the optimization problem, an inverse lithography technology tool can employ a cost function representing the “goodness” of the mask solution. Eq. ζ1) shows an example cost function G that expresses a deviation of the image I(x,y) from the threshold constant T along the target contours CG:

$$G = {\sum }_{i} {\int }_{{C}_{i}} {( I ( ξ η ) - T )}^{2} dl \to min . \qquad ( 1 )$$

Here ζ=ζ(l) and η=η(l) are Cartesian coordinates along the target contours; dl represents a contour integration element. The image I(x,y) is controlled by the mask, thus G depends on the mask transmission m=m(x,y), a complex-valued piece-wise constant function. Thus the constrained optimization problem may be stated as finding the mask m=m(x,y) that minimizes

$$G [ m ] \to min , \qquad ( 2 )$$

while constraining acceptable values of the mask transmission function to the constants mₘᵢₙ and 1. For chrome masks mₘᵢₙ=0. For OMOG (opaque MoSi on glass) masks mₘᵢₙ is a complex constant mₘᵢₙ≈(0.023, −0.022). The inverse lithography technology tool tries to find an analytical representation of the gradient of the objective, and then may use fast Fourier transformation to quickly calculate it.

The analytical expression for the gradient of the objective can be found by perturbing the mask m→m+δm and then finding the linear part of the perturbation of the objective SG. In the case of the cost function shown in Eq. ζ1), the following analytical expression for the gradient may be obtained:

$$g ( x , y ) = 4 Re {\sum }_{k = 1}^{N} λ {\sum }_{i} {\int }_{{C}_{i}} ( ς η - ) * ξ η ( ξ - η - y ) dl \\ I ( x , y ) = {\sum }_{k = 1}^{N} {λ}_{k} {A}_{k}^{*} ( x , y ) {A}_{k} ( x , y ) \\ {A}_{k} = {K}_{k} ( x , y ) ⊗ m ( x , y ) \qquad ( 3 )$$

where N is the total number of optical kernels, n are weights of the optical kernels, Aₙ is the electrical field from the n-th kernel Kn. The discretized version of (3) can be quickly calculated through fast Fourier transformations.

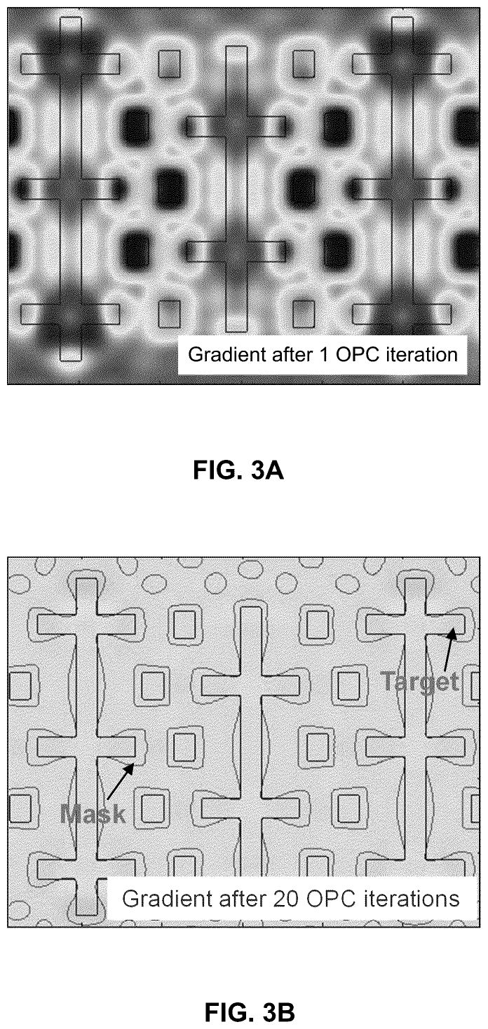

The gradient g(x,y) of the objective is used in an iterative procedure to move mask contours or to modify mask transmissions in a manner that reduced the value of the cost function G. Sub-resolution assist features (SRAFs) are automatically generated in such an inverse lithography process. FIG. 3A illustrates an example of a mask pattern after one iteration and FIG. 3B illustrates an example of a mask pattern after 20 iterations. In the figures, the gradient is represented by colors. The bright yellow and blue colors indicate regions where the mask contour should be expanded while the dark orange and red colors indicate regions where the mask contour should be contracted. After one iteration, the gradient magnitude varies across the design patterns. After 20 iterations, the gradient magnitude becomes smaller and the cost function approaches a minimum.

The above described ILT approach is just one example. There are various other ILT approaches which the disclosed technology can employ.

### SRAF Generation Tool

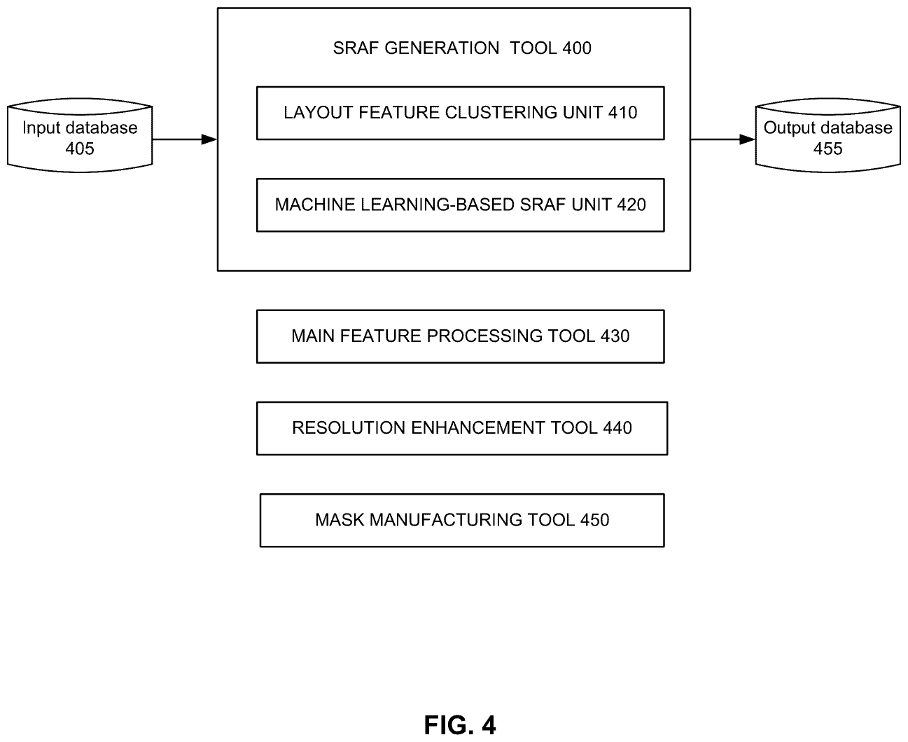

FIG. 4 illustrates an example of a SRAF generation tool 400 that may be implemented according to various embodiments of the disclosed technology. As seen in this figure, the SRAF generation tool 400 includes a layout feature clustering unit 410 and a machine learning-based SRAF unit 420. Various implementations of the SRAF generation tool 400 may cooperate with (or incorporate) one or more of a main feature processing tool 430, a resolution enhancement tool 440, a mask manufacturing tool 450, an input database 405 and an output database 455.

As will be discussed in more detail below, the SRAF generation tool 400 can receive a layout design from the input database 405. The layout feature clustering unit 410 can classify layout features in the layout design into groups of layout features. The machine learning-based SRAF unit 420 can generate sub-resolution assist features (SRAF) for layout features in each of the groups of layout features. The machine learning-based SRAF unit 420 can use a specific machine learning model for each of the groups of layout features to determine whether a small area should be part of a sub-resolution assist feature. The SRAF generation process can comprise: dividing regions where sub-resolution assist features are likely to be placed into areas of interest, extracting a feature vector for each of the areas of interest based on a layout area centered at the each of the areas of interest, determining whether the each of the areas of interest should be part of a sub-resolution assist feature by using the feature vector as an input of the specific machine learning model, and generating the sub-resolution assist features based on results of the determining. The SRAF generation tool 400 can store information of the sub-resolution assist features in the output database 455.

The main feature processing tool 430 can generate modified layout features by performing an optical proximity correction process on the layout features in the layout design. The optical proximity correction process can be a conventional optical proximity correction process or an inverse lithography technology process. The sub-resolution assist features generated by the SRAF generation tool 400 can be combined with the modified layout features generated by the main feature processing tool 430 to generate a processed layout design. The resolution enhancement tool 440 can perform an optical proximity correction process on the processed layout design to generate a final processed layout design. Again, this optical proximity correction process can be a conventional optical proximity correction process or an inverse lithography technology process. The mask manufacturing tool 450 can manufacture photo masks using the final processed layout design which are derived based on the information of the sub-resolution assist features.

As previously noted, various examples of the disclosed technology may be implemented by one or more computing systems, such as the computing system illustrated in FIGS. 1 and 2. Accordingly, one or more of the layout feature clustering unit 410, the machine learning-based SRAF unit 420, the main feature processing tool 430, and the resolution enhancement tool 440 may be implemented by executing programming instructions on one or more processors in one or more computing systems, such as the computing system illustrated in FIGS. 1 and 2. Correspondingly, some other embodiments of the disclosed technology may be implemented by software instructions, stored on a non-transitory computer-readable medium, for instructing one or more programmable computers/computer systems to perform the functions of one or more of the layout feature clustering unit 410, the machine learning-based SRAF unit 420, the main feature processing tool 430, and the resolution enhancement tool 440. As used herein, the term “non-transitory computer-readable medium” refers to computer-readable medium that are capable of storing data for future retrieval, and not propagating electro-magnetic waves. The non-transitory computer-readable medium may be, for example, a magnetic storage device, an optical storage device, or a solid state storage device.

It also should be appreciated that, while the layout feature clustering unit 410, the machine learning-based SRAF unit 420, the main feature processing tool 430, and the resolution enhancement tool 440 are shown as separate units in FIG. 4, a single computer (or a single processor within a master computer) or a single computer system may be used to implement some or all of these units at different times, or components of these units at different times.

With various examples of the disclosed technology, the input database 405 and the output database 455 may be implemented using any suitable computer readable storage device. That is, either of the input database 405 and the output database 455 may be implemented using any combination of computer readable storage devices including, for example, microcircuit memory devices such as read-write memory (RAM), read-only memory (ROM), electronically erasable and programmable read-only memory (EEPROM) or flash memory microcircuit devices, CD-ROM disks, digital video disks (DVD), or other optical storage devices. The computer readable storage devices may also include magnetic cassettes, magnetic tapes, magnetic disks or other magnetic storage devices, holographic storage devices, or any other non-transitory storage medium that can be used to store desired information. While the input database 405 and the output database 455 are shown as separate units in FIG. 4, a single data storage medium may be used to implement some or all of these databases.

### Monotonic Machine Learning-Based SRAF Generation Process

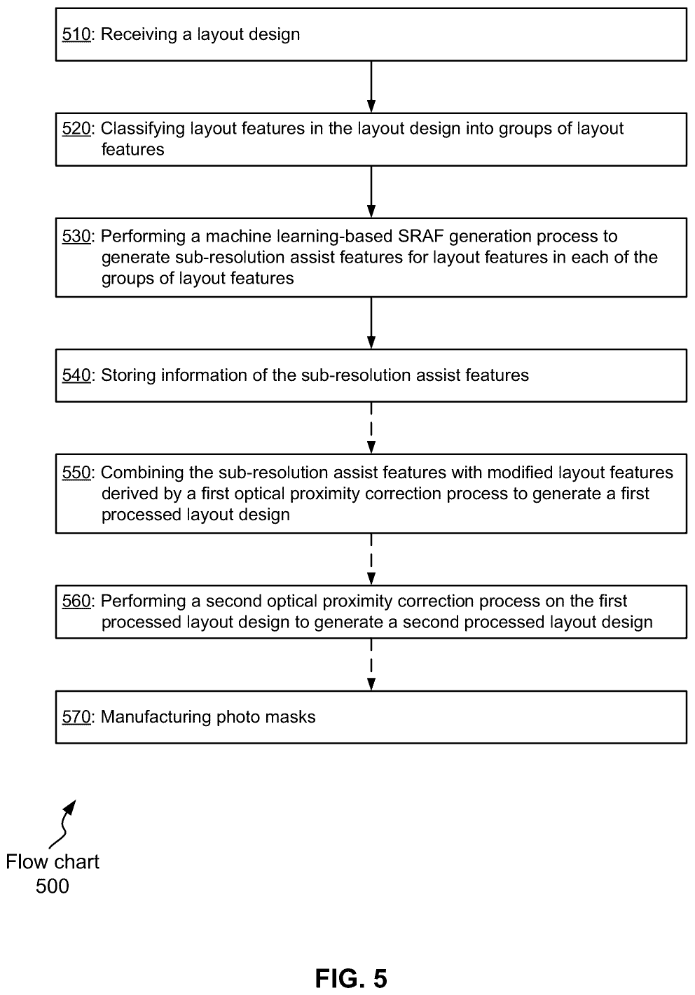

FIG. 5 illustrates a flowchart 500 showing a monotonic machine learning-based SRAF generation process that may be implemented according to various examples of the disclosed technology. For ease of understanding, methods of monotonic machine learning-based SRAF generation that may be employed according to various embodiments of the disclosed technology will be described with reference to the SRAF generation tool 400 in FIG. 4 and the flow chart 500 illustrated in FIG. 5. It should be appreciated, however, that alternate implementations of an SRAF generation tool may be used to perform the methods of monotonic machine learning-based SRAF generation illustrated by the flow chart 500 according to various embodiments of the disclosed technology. Likewise, the SRAF generation tool 400 may be employed to perform other methods of monotonic machine learning-based SRAF generation according to various embodiments of the disclosed technology.

In operation 510 of the flow chart 500, the SRAF generation tool 400 receives a layout design from the input database 405. The layout design may be in the GDSII standard format or the OASIS standard format. The layout design may be derived from a circuit design using a place and route tool. Alternatively, the layout design may be one that has been processed by a resolution enhancement tool. The layout design may represent a full-chip design or a portion of a full-chip design.

In operation 520, the layout feature clustering unit 410 classifies layout features in the layout design into groups of layout features. Layout features can be edge fragments or layout patterns comprising polygons. The layout feature clustering unit 410 can employ various pattern clustering techniques. The pattern clustering techniques include those based on conventional fuzzy pattern matching and machine learning-based techniques. One of the machine learning-based techniques is a hyperspace-based machine learning technique. In the hyperspace-based machine learning process, the layout feature clustering unit 410 can first extract a feature vector for each of the layout features. To extract the feature vector for a particular layout feature, a layout region centered at the layout feature may be considered. The size of a layout region can be set based upon the range of diffraction or process effects. Printing errors of a layout feature can be caused by its neighboring layout features. How far away a neighboring layout feature can affect the printability depends at least in part on the wavelength of the light source used for lithography. The size of a layout region can thus be set as several multiples of the wavelength or the minimum line spacing that can be achieved in a particular technology node. In a state-of-the-art deep ultraviolet (DUV) lithography process, the light source is 193 nm excimer lasers. The minimum metal line width in single exposure for the 7 nm or 10 nm technology node is about 40 nm. Accordingly, the layout region can be set as, for example, 200 nm in radius for a circle shape or 400 nm in side length for a square shape.

The feature vector can comprise density-based components. For example, one density-based component of the feature vector can correspond to a ring in a set of rings. The plurality of rings do not overlap with each other and cover a whole area of a circle when being placed together. To derive values of the density-based components for a layout feature, the layout feature clustering unit 410 can place the set of rings on the layout region centered at the layout feature and compute the percentage of area in each of the rings occupied by layout features in the layout region.

Additionally or alternatively, the feature vector can comprise other types of components. Geometry-based feature vector components such as critical dimensions and fragment lengths may be included. Other candidates for feature vector components may be related to manufacturing process. For example, some feature vector components may be associated with the optical models used for lithographic simulation, capturing properties such as light intensity information. Some other feature vector components may be related to resist models. The feature vector can be designed to contain attributes encapsulating the domain knowledge of both design and process and to include information on design layout, the lithography and etch process models, OPC/RET recipes, and fab metrology equipment. Users can define their own custom feature vectors.

In the hyperspace-based machine learning technique, a hyperspace may refer to or include a coordinate space with multiple dimensions to map multiple parameter values of data points in a dataset (whether directly or as transformed parameters), and with at least a portion of the coordinate system partitioned into hyperboxes. Hyperboxes of a generated hyperspace may be used to process large datasets in an efficient and accurate manner. As described in greater detail herein, a hyperspace may be generated by transforming a feature space of a dataset (feature vectors) and quantizing the transformed feature space into hyperboxes. Processing of the dataset may be performed by processing the quantized hyperboxes of the hyperspace that contain at least one or more mapped feature vectors of the dataset. The hyperspace generation and hyperspace-based processing features may have O (n) complexity, and the described hyperspace features may thus exhibit increased computational efficiency and speed as compared to other O (n²) processing techniques such as K-means clustering and Mahalanobis cluster computations.

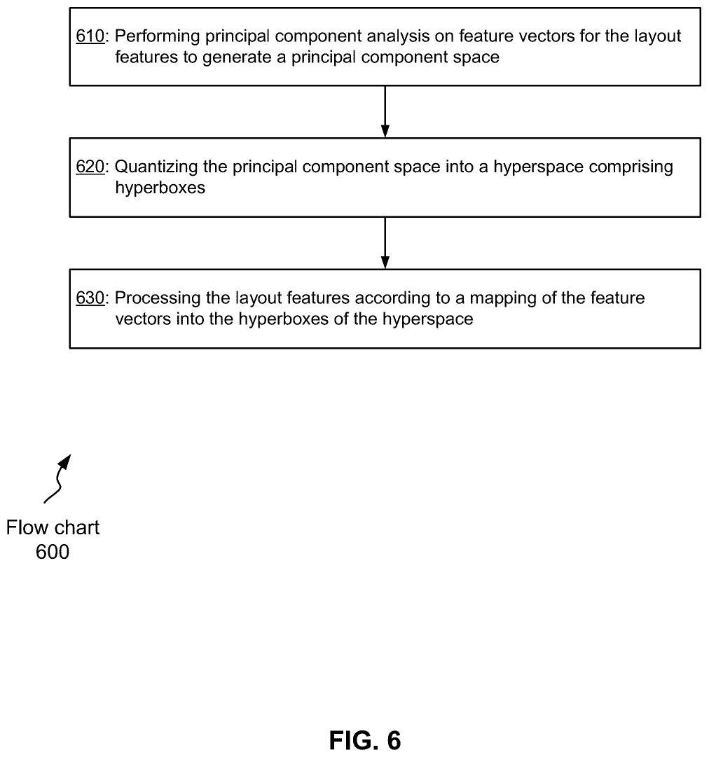

FIG. 6 illustrates a flowchart 600 showing a process for using a hyperspace-based machine learning technique to classify layout features that may be implemented according to various examples of the disclosed technology. In operation 610, the layout feature clustering unit 410 performs principal component analysis (or any other multi-variate transformation) on feature vectors to generate a principal component space. The space where the feature vectors are located may be referred to as feature space. The feature vectors are extracted from layout regions centered at the layout features, respectively, to represent the layout features. In another word, the layout features are mapped in the feature space as the feature vectors. By performing principal component analysis on the feature vectors, the layout feature clustering unit 410 can map the feature vectors into the principal component space, which is a different coordinate system that further correlates the parameter values of the layout features and supports variance determinations through the transformation.

In some implementations, the layout feature clustering unit 410 may perform the transformation from a feature space into a corresponding principal component space using a covariance (or correlation) matrix. Eigenvectors of the covariance matrix may represent how each parameter of a feature space maps to each principal component of the principal component space. The layout feature clustering unit 410 may further determine eigenvalues for each principal component of a principal component space, and determined principal component eigenvalues may represent the dataset variance attributable to the principal component (e.g., a higher eigenvalue may indicate that a given principal component exhibits, measures, or characterizes a greater data variance relative to other principal components with lower eigenvalues). The transformation can be equivalent to a rotation of the principal component axes from the feature space based on eigenvalues determined for the principal components of the principal component space.

In operation 620, the layout feature clustering unit 410 quantizes the principal component space into a hyperspace comprising hyperboxes. The layout feature clustering unit 410 can determine dimension values of the hyperboxes to specifically account for variance among parameters of the principal component space (e.g., based on variance attributable to the principal components of the transformed feature space). Quantizing the principal component space may refer to partitioning at least a portion of the principal component space into hyperboxes. A hyperbox may refer to an ‘n’-dimensional enclosed shape with hyperbox dimension values along each dimension of the principal component space. In particular, the number of dimensions of hyperboxes may be equal to the number of dimensions of the principal component space. According to some embodiments of the disclosed technology, the layout feature clustering unit 410 can set the dimension size of hyperboxes along one principal component axis of the first principal component as a function of a value range for the first principal component and a predetermined divider value. The first principal component may be the principal component having the highest variance among the principal components of the principal component space. In particular, the layout feature clustering unit 410 may determine a value range (between a minimum value and a maximum value) of the first principal component for the set of feature vectors mapped into the principal component space. The layout feature clustering unit 410 may then divide the value range by the predetermined divider value. By adjusting the divider value, the layout feature clustering unit 410 can flexibly control how granular, precise, sparse, or dense the hyperbox partitioning in a quantized hyperspace will be. For the remaining principal components, the layout feature clustering unit 410 may determine dimension values as a function of the value range for the remaining principal components respectively, the predetermined divider value, and a variance ratio between the first and the remaining principal components respectively (e.g., as measured through the determined eigenvalues of the principal components). By accounting for variance ratios in hyperbox dimension value determinations, the layout feature clustering unit 410 may partition a range of values along a particular principal component for a transformed feature space at lesser granularity or precision as compared to the number of partitions for the first principal component. Quantizing the principal component space into a hyperspace comprised of hyperboxes effectively partitions the principal component space into different bins, clusters, or partitions. Each hyperbox of the hyperspace may act as a cluster element by which the layout features can be processed. The layout feature clustering unit 410 can vary the number of bins/clusters/partitions by changing the divider value. Hyperbox dimension determination and transformed feature space quantization may be performed in O (n) time, allowing for clustering of transformed feature vectors for layout features with increased computational efficiency while nonetheless supporting analyses that account for dataset variance.

In operation 630, the layout feature clustering unit 410 processes the layout features according to a mapping of the feature vectors into the hyperboxes of the hyperspace. The layout feature clustering unit 410 can use the covariance matrix to map the feature vectors into the hyperspace. Each of the transformed feature vectors may be bound by a respective hyperbox in the hyperspace. The transformed feature vectors encapsulated by the same hyperbox may form a cluster for processing purposes. As such, the layout feature clustering unit 410 may group these multiple feature vectors (and corresponding layout features) as part of a same cluster.

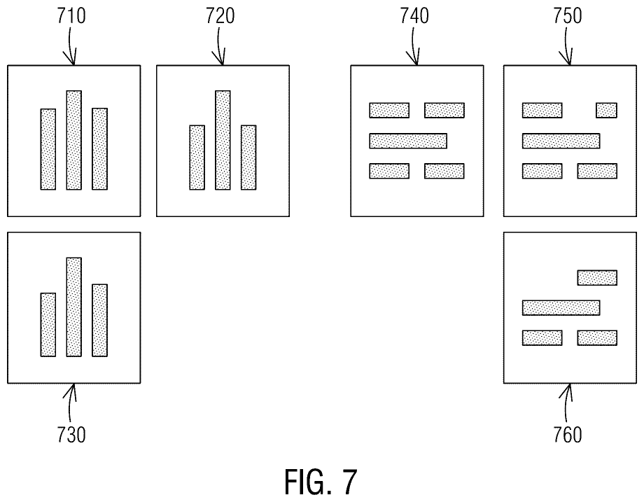

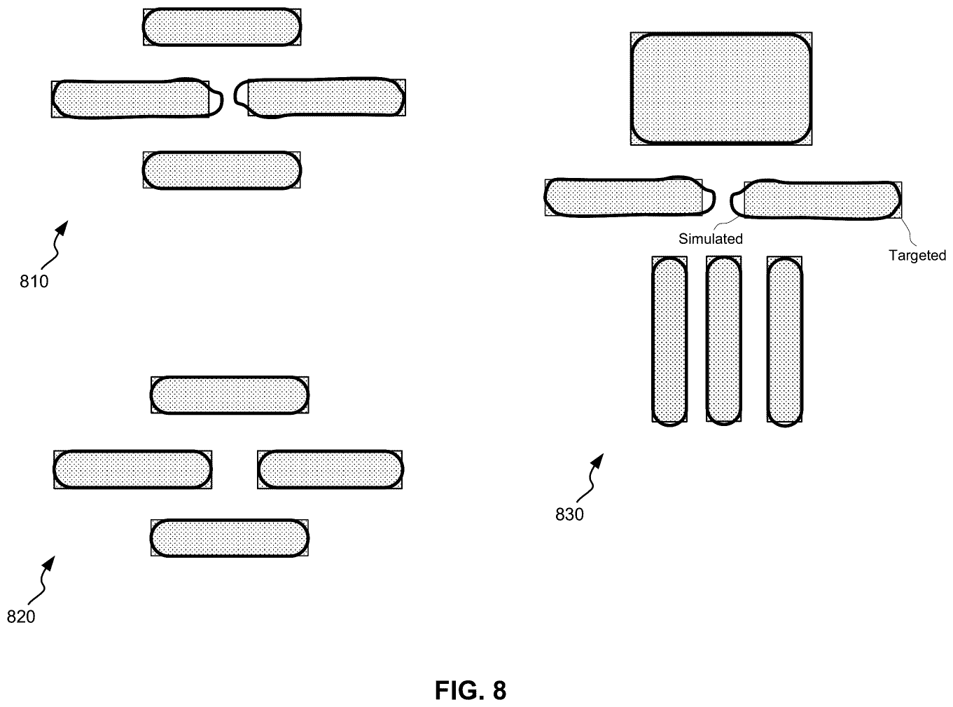

FIG. 7 illustrates an example clustering result from a hyperspace-based machine learning process. The figure shows two groups of layout features. The first group of layout features include layout features 710, 720 and 730, and the second group of layout features include layout features 740, 750 and 760. The layout features in each group are not the same, but the hyperspace-based machine learning process groups them together. Experiments have shown the clustering results by the hyperspace-based machine learning process correlate well with design and fab printing behavior. FIG. 8 illustrates another example clustering result from a hyperspace-based machine learning process. The figure shows both targeted and simulated wafer contours of three layout features 810, 820 and 830. In appearance, the layout features 810 and 820 are more similar to each other than either of them is to the layout feature 830. However, the hyperspace-based machine learning process groups the layout features 810 and 830 together but assigns the layout feature 820 to another group. This clustering result actually correlates well with design and fab printing behavior since the simulated wafer contours of the layout features 810 and 830 indicates the same printability problem (bridging) in a lithography process while the simulated wafer contours of the layout feature 820 does not.

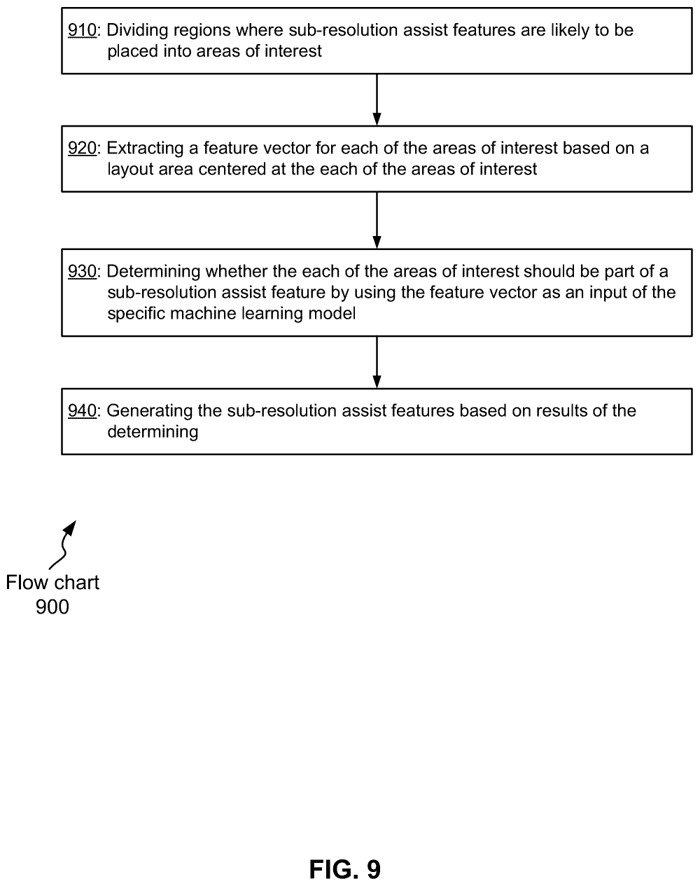

Referring back to FIG. 5, in operation 530, the machine learning-based SRAF unit 420 performs a machine learning-based SRAF generation process to generate sub-resolution assist features for layout features in each of the groups of layout features. The machine learning-based SRAF unit 420 can use a specific machine learning model for each of the groups of layout features to determine whether a small area should be part of a sub-resolution assist feature. FIG. 9 illustrates a flowchart 900 showing a process for generating sub-resolution assist features for each of the groups of layout features that may be implemented according to various examples of the disclosed technology. In operation 910, the machine learning-based SRAF unit 420 divides regions where sub-resolution assist features are likely to be placed into areas of interest. The regions where sub-resolution assist features are likely to be placed can be determined using various methods. A simple approach is to treat all regions unoccupied by layout features as the regions where sub-resolution assist features are likely to be placed. Alternatively, heuristics or rule-based SRAF methods may be employed to identify more likely candidates from all unoccupied regions.

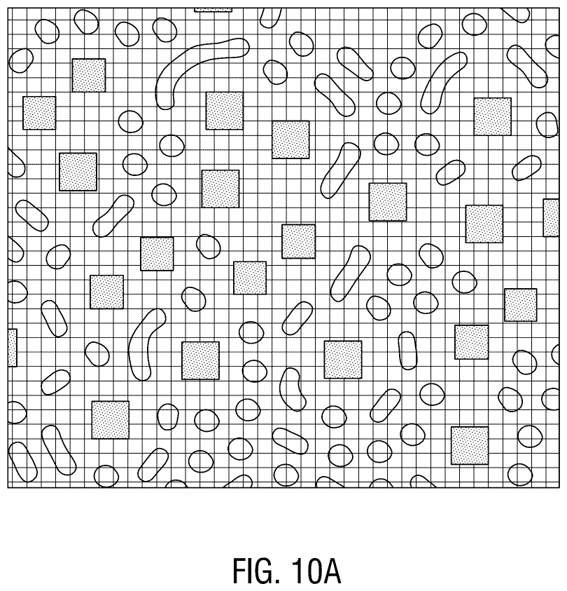

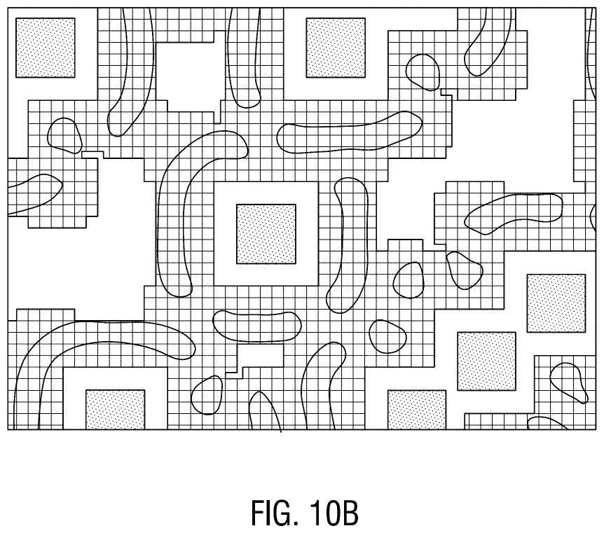

The areas of interest have the same size and shape as the small area used by the machine learning models. The size and shape of the small area used by the machine learning models can be preset. They can be set before the machine models are trained. One example of the small area is a square with a side length value in between 50 nm and 20 nm. FIGS. 10A and 10B illustrate two examples of regions where sub-resolution assist features are likely to be placed being dividing into areas of interest. In the two figures, all main features are vias (elements provides an electrical path between different layout layers) represented by big squares and the areas of interest are small squares. In FIG. 10A, regions where sub-resolution assist features are likely to be placed are all regions unoccupied by the vias. In FIG. 10B, regions where sub-resolution assist features are likely to be placed are only part of unoccupied regions determined based on heuristics or a rule-based SRAF method.

In operation 920, the machine learning-based SRAF unit 420 extracts a feature vector for each of the areas of interest based on a layout area centered at the each of the areas of interest. The feature vector can comprise density-based components, other geometry-based components, manufacturing process-related components, or any other combination thereof. The feature vector for SRAF generation can be the same as or different from the one employed for layout feature clustering purposes described in the operation 520 of the flow chart 500. The layout area centered at an area of interest for the feature vector extraction can be set as several multiples of the wavelength or the minimum line spacing that can be achieved in a particular technology node. For example, the layout area can be set as 200 nm in radius for a circle shape or 400 nm in side length for a square shape.

In a conventional SRAF generation process, no matter whether it is rule-based, model-based, or machine learning-based, determining whether to insert an SRAF in a certain location near a main feature typically focuses on this particular main feature. This can cause problems of accuracy and consistency due to other main features in the surrounding area. These problems, however, can be addressed by shifting the focus from the particular main feature to the location where an SRAF may be generated since the feature vector derived this way can take into account optical proximity effects associated with all surrounding main features more accurately.

In operation 930, the machine learning-based SRAF unit 420 determines whether the each of the areas of interest should be part of a sub-resolution assist feature by using the feature vector as an input of the specific machine learning model. A machine learning model for a group of layout features can be constructed using training samples that can be classified into the same group of layout features. The training samples can be labeled based on sub-resolution assist features that are generated by an inverse lithography technology (ILT) tool.

As mentioned previously, inverse lithography technology can deliver better quality of sub-resolution assist features than conventional SRAF techniques. This is due, at least in part, to the facts that sub-resolution assist features are automatically generated and that they tend to be curvilinear in nature. The machine learning model trained based on inverse lithography technology can generate sub-resolution assist features similar to those obtained by using inverse lithography technology directly. On the other hand, each of the training samples itself is much smaller than a full layout design. Thus, the inverse lithography technology process can be finished in a reasonable period of time. As such, the disclosed technology can realize the benefits of inverse lithography technology without suffering its high computation costs. The training samples can be extracted from real layout designs including from the layout design under processing or generated by a software tool such as the Calibre Layout Schema Generator by Siemens Industry Software Inc.

In this machine learning application, each of the machine learning models is trained for only one of the groups of layout features to mitigate the impact of overfitting. The overfitting problem is often encountered in a machine-learning process due to non-optimized model structure or insufficient training samples. Focusing on a single cluster of similar layout features can narrow the scope of modeling space and thus reduce the number of training samples needed. Further, machine learning models constructed this way can be tolerant of layout pattern changes from different development cycles. Adding/deleting training data will only have impact on the corresponding group's nodes while other nodes can be kept untouched. The prediction process is also controllable. If the prediction for a group of layout features does not work well with the initial model, these specific hotspots can be fixed by simply adjusting the training samples for it.

In operation 940, the machine learning-based SRAF unit 420 generates sub-resolution assist features based on results of the operation 930. The generation may comprise combining areas of interest determined to be part of a sub-resolution assist feature to form intermediate sub-resolution assist features, and then processing the intermediate sub-resolution assist features to derive the sub-resolution assist features. In FIG. 10B, the squares predicted to be part of sub-resolution assist features are merged. The derived intermediate sub-resolution assist features may not have smooth boundaries. Thus, the processing of intermediate sub-resolution assist features can comprise smoothing the boundaries, making widths of intermediate sub-resolution assist features equal, or both. The processing may further comprise modifying the intermediate sub-resolution assist features to make them MRC(mask rule checking)—clean based on mask rules provided by mask making companies.

In operation 950, the SRAF generation tool 400 stores information of the sub-resolution assist features in the output database 455.

Optionally, in operation 550, the main feature generation tool 430 generates modified layout features and combines them with the sub-resolution assist features to form a first processed layout design. The main feature generation tool 430 can use a conventional optical proximity correction technique or a machine learning-based technique to generate the modified layout features. For example, similar to generating the sub-resolution assist features, the main feature generation tool 430 can employ a specific machine learning model for each of the groups of layout features to determine how a layout feature in the each of the groups of layout features is modified to correct optical proximity effects. The specific machine learning model can be trained using samples labeled based on inverse lithography technology.

Optionally, in operation 560, the resolution enhancement tool 440 performs a second optical proximity correction process on the first processed layout design to generate a second processed layout design. The resolution enhancement tool 440 can be implemented by or incorporate an inverse lithography technology tool or a conventional OPC tool that can generate curvilinear layout features. The process can be fast because the first processed layout design is close to be optimized for correcting optical proximity effects after separate main feature and SRAF processing processes.

The resolution enhancement tool 440 may further perform mask process correction (MPC) on the processed layout design. Although the photomask features are typically used in a 4× reduction system, and the feature dimensions are thus 4× larger than on the wafer, there is still a need to accurately fabricate SRAF and other OPC jogs and structures that are significantly smaller. Mask process correction attempts to correct charged particle proximity effects.

Optionally, in operation 570, the mask manufacturing tool 450 can manufacture masks based on the second processed layout design. The masks can be used to fabricate chips through photolithography.

### CONCLUSION

While the disclosed technology has been described with respect to specific examples including presently preferred modes of carrying out the disclosed technology, those skilled in the art will appreciate that there are numerous variations and permutations of the above described systems and techniques that fall within the spirit and scope of the disclosed technology as set forth in the appended claims. For example, while specific terminology has been employed above to refer to electronic design automation processes, it should be appreciated that various examples of the disclosed technology may be implemented using any desired combination of electronic design automation processes.

What is claimed is:

1. A method, executed by at least one processor of a computer, comprising:
receiving a layout design;
classifying layout features in the layout design into groups of layout features;
performing a machine learning-based SRAF generation process to generate sub-resolution assist features for layout features in each of the groups of layout features, each of the groups of layout features having a specific machine learning model for determining whether a small area should be part of a sub-resolution assist feature, size and shape of the small area being preset, the machine learning-based SRAF generation process comprising:
dividing regions where sub-resolution assist features are likely to be placed into areas of interest, each of the areas of interest having the same size and shape as the small area,
extracting a feature vector for each of the areas of interest based on a layout area centered at the each of the areas of interest,
determining whether the each of the areas of interest should be part of a sub-resolution assist feature by using the feature vector as an input of the specific machine learning model, and
generating the sub-resolution assist features based on results of the determining; and
storing information of the sub-resolution assist features.

2. The method recited in claim 1, wherein the specific machine learning model is trained using training samples labeled based on sub-resolution assist features generated by an inverse lithography technology (ILT) tool.

3. The method recited in claim 1, wherein the small area is a square with a side length smaller than 50 nm, and the layout area centered at each of the areas of interest has a dimension smaller than 1 micron.

4. The method recited in claim 1, wherein the generating the sub-resolution assist features based on results of the determining comprises:
combining areas of interest determined to be part of a sub-resolution assist feature to form intermediate sub-resolution assist features; and
processing the intermediate sub-resolution assist features to derive the sub-resolution assist features.

5. The method recited in claim 1, wherein the classifying layout features is a machine learning-based clustering process.

6. The method recited in claim 5, wherein the machine learning-based clustering process comprises:
extracting a feature vector for each of the layout features; and
mapping the set of feature vectors into hyperboxes of a hyperspace.

7. The method recited in claim 1, further comprising:
combining the sub-resolution assist features with modified layout features to generate a first processed layout design, the modified layout features being generated by performing a first optical proximity correction process on the layout features in the layout design; and
performing a second optical proximity correction process on the first processed layout design to generate a second processed layout design which is to be used to manufacture photo masks.

8. The method recited in claim 7, wherein the first optical proximity correction process is a machine learning-based main feature generation process which generates the modified layout features for layouts features in each of the groups of layout features using a particular machine learning model for the each of the groups of layout features.

9. The method recited in claim 1, further comprising:
manufacturing photo masks based on the information of the sub-resolution assist features.

10. One or more computer-readable media storing computer-executable instructions for causing one or more processors to perform a method, the method comprising:
receiving a layout design;
classifying layout features in the layout design into groups of layout features;
performing a machine learning-based SRAF generation process to generate sub-resolution assist features for layout features in each of the groups of layout features, each of the groups of layout features having a specific machine learning model for determining whether a small area should be part of a sub-resolution assist feature, size and shape of the small area being preset, the machine learning-based SRAF generation process comprising:
dividing regions where sub-resolution assist features are likely to be placed into areas of interest, each of the areas of interest having the same size and shape as the small area,
extracting a feature vector for each of the areas of interest based on a layout area centered at the each of the areas of interest,
determining whether the each of the areas of interest should be part of a sub-resolution assist feature by using the feature vector as an input of the specific machine learning model, and
generating the sub-resolution assist features based on results of the determining; and
storing information of the sub-resolution assist features.

11. The one or more computer-readable media recited in claim 10, wherein the specific machine learning model is trained using training samples labeled based on sub-resolution assist features generated by an inverse lithography technology (ILT) tool.

12. The one or more computer-readable media recited in claim 10, wherein the small area is a square with a side length smaller than 50 nm, and the layout area centered at each of the areas of interest has a dimension smaller than 1 micron.

13. The one or more computer-readable media recited in claim 10, wherein the generating the sub-resolution assist features based on results of the determining comprises:
combining areas of interest determined to be part of a sub-resolution assist feature to form intermediate sub-resolution assist features; and
processing the intermediate sub-resolution assist features to derive the sub-resolution assist features.

14. The one or more computer-readable media recited in claim 10, wherein the classifying layout features is a machine learning-based clustering process.

15. The one or more computer-readable media recited in claim 14, wherein the machine learning-based clustering process comprises:
extracting a feature vector for each of the layout features; and
mapping the set of feature vectors into hyperboxes of a hyperspace.

16. The one or more computer-readable media recited in claim 10, wherein the method further comprises:
combining the sub-resolution assist features with modified layout features to generate a first processed layout design, the modified layout features being generated by performing a first optical proximity correction process on the layout features in the layout design; and
performing a second optical proximity correction process on the first processed layout design to generate a second processed layout design which is to be used to manufacture photo masks.

17. The one or more computer-readable media recited in claim 10, wherein the first optical proximity correction process is a machine learning-based main feature generation process which generates the modified layout features for layouts features in each of the groups of layout features using a particular machine learning model for the each of the groups of layout features.

18. A system, comprising:
one or more processors, the one or more processors programmed to perform a method, the method comprising:
receiving a layout design;
classifying layout features in the layout design into groups of layout features;
performing a machine learning-based SRAF generation process to generate sub-resolution assist features for layout features in each of the groups of layout features, each of the groups of layout features having a specific machine learning model for determining whether a small area should be part of a sub-resolution assist feature, size and shape of the small area being preset, the machine learning-based SRAF generation process comprising:
dividing regions where sub-resolution assist features are likely to be placed into areas of interest, each of the areas of interest having the same size and shape as the small area,
extracting a feature vector for each of the areas of interest based on a layout area centered at the each of the areas of interest,
determining whether the each of the areas of interest should be part of a sub-resolution assist feature by using the feature vector as an input of the specific machine learning model, and
generating the sub-resolution assist features based on results of the determining; and
storing information of the sub-resolution assist features.

19. The system recited in claim 18, wherein the specific machine learning model is trained using training samples labeled based on sub-resolution assist features generated by an inverse lithography technology (ILT) tool.

20. The system recited in claim 18, wherein the generating the sub-resolution assist features based on results of the determining comprises:
combining areas of interest determined to be part of a sub-resolution assist feature to form intermediate sub-resolution assist features; and
processing the intermediate sub-resolution assist features to derive the sub-resolution assist features.

21. The system recited in claim 18, wherein the classifying layout features is a machine learning-based clustering process.

22. The system recited in claim 18, wherein the method further comprises:
combining the sub-resolution assist features with modified layout features to generate a first processed layout design, the modified layout features being generated by performing a first optical proximity correction process on the layout features in the layout design; and
performing a second optical proximity correction process on the first processed layout design to generate a second processed layout design which is to be used to manufacture photo masks.

23. The system recited in claim 22, wherein the first optical proximity correction process is a machine learning-based main feature generation process which generates the modified layout features for layouts features in each of the groups of layout features using a particular machine learning model for the each of the groups of layout features.
